(19) United States
(12) Patent Application Publication
(10) Pub. No.: US 2004/0014327 A1
(43) Pub. Date: Jan. 22, 2004

(54) Method for etching high dielectric constant materials and for cleaning deposition chambers for high dielectric constant materials

(76) Inventors: Bing Ji, Allentown, PA (US); Stephen Andrew Motika, Kutztown, PA (US); Ronald Martin Pearlstein, Macungie, PA (US); Eugene Joseph Karwacki JR., Orefield, PA (US)

Correspondence Address: AIR PRODUCTS AND CHEMICALS, INC., PATENT DEPARTMENT, 7201 HAMILTON BOULEVARD, ALLENTOWN, PA, 181951501

(21) Appl. No.: 10/198,509

(22) Filed: Jul. 18, 2002

(51) Int. Cl. H01L 21/461

(52) U.S. Cl. 438/722

(57) ABSTRACT

A process for removing a substance from a substrate, includes: (1) providing the substrate, wherein: (a) the substrate is at least partially coated with the substance; (b) the substance is a transition metal oxide, a transition metal silicate, a Group 13 metal oxide, a Group 13 metal silicate, or mixtures thereof; and (c) the substance has a dielectric constant greater than silicon dioxide; (2) reacting the substance with a reactive gas to form a volatile product, wherein the reactive gas comprises chlorine; and (3) removing the volatile product from the substrate to thereby remove the substance from the substrate, provided that when the substance is Al₂O₃ and the substrate is a semiconductor from which the substance is being selectively etched, the process is conducted in the absence of a plasma having a density greater than 10¹¹ cm⁻³. The process is particularly suitable for etching semiconductors and for cleaning reaction chambers.

### BACKGROUND OF THE INVENTION

This invention relates to a method to etch high-k dielectric materials deposited on a substrate, and a method to clean residues from the internal surfaces of a reactor in which these high-k dielectric films are deposited. More specifically, this invention relates to etching and/or cleaning metal-oxide high-k dielectric materials such as Al₂O₃, HfO₂, ZrO₂, etc. and mixtures thereof, and metal silicate high-k dielectric materials such as HfSiₓO_{y}, ZrSiₓO_{y}, etc. and mixtures thereof.

In the manufacture of semiconductor integrated circuits (IC), dielectric materials such as silicon dioxide (SiO₂), silicon nitride (Si₃N₄), and silicon oxynitride (SiON) have been widely used as insulators for transistor gates. Such insulators are often called gate dielectrics. As IC device geometry shrinks, gate dielectric layers have become progressively thinner. When the gate dielectric layer approaches thicknesses of a few nanometers or less, conventional SiO₂, Si₃N₄, and SiON materials undergo electric breakdown and no longer provide insulation. To maintain adequate breakdown voltage at very small thickness (≦10 nm), high dielectric constant materials (i.e., high-k materials, which for present purposes are defined as materials where k is greater than about 4.42, the k of silicon dioxide) must be used as the gate insulating layer. The IC industry has experimented with many high-k materials. The latest and most promising high-k materials are metal oxides such as Al₂O₃, HfO₂, ZrO₂, and mixtures thereof, and metal silicates such as HfSiₓO_{y}, ZrSiO₄, and mixtures thereof.

High-k materials such as Al₂O₃, HfO₂, and ZrO₂ are very stable and resistive against most of the etching reactions, which has led to their use as etch stop layers and hard mask layers in plasma etching of other materials. See, e.g., K. K. Shih et al., “Hafnium dioxide etch-stop layer for phase-shifting masks”, J. Vac. Sci. Technol. B 11(6), pp. 2130-2131 (1993); J. A. Britten, et al., “Etch-stop characteristics of Sc₂O₃ and HfO₂ films for multilayer dielectric grating applications”, J. Vac. Sci. Technol. A 14(5), pp. 2973-2975 (1996); J. Hong et al., “Comparison of Cl₂ and F₂ based chemistries for the inductively coupled plasma etching of NiMnSb thin films”, J. Vac. Sci. Technol. A 17(4), pp. 1326-1330 (1999); U.S. Pat. No. 5,972,722 to Visokay et al.; U.S. Pat. No. 6,211,035 B1 to Moise et al., U.S. patent application Publication US2001/0055852 A1 to Moise et al.; and EP 1,001,459 A2 to Moise et al.

These high-k materials are typically deposited from chemical precursors that are reacted in a deposition chamber to form films in a chemical vapor deposition (CVD) process. In some instances, these high-k materials are deposited onto semiconductor substrates (wafers) by atomic layer deposition (ALD), in which the films are deposited in controlled, nearly monoatomic layers. Apparatus and processes for performing ALD are disclosed in, e.g., U.S. Pat. No. 5,879,459 to Gadgil et al., U.S. Pat. No. 6,174,377 B1 to Doering et al., U.S. patent application Publication US2001/0011526 A1 to Doering et al., U.S. Pat. No. 6,387,185 B2 to Doering et al., WO 00/40772 to Doering et al. and WO 00/79019 Al to Gadgil et al. This family of patents assigned to Genus, Inc. teaches that “In situ plasma cleans allow the realization of a very long time between maintenance cleaning.” (See, e.g., U.S. Pat. No. 6,387,185 B2 at column 7, lines 27-28.) However, no details of any process for plasma cleaning of ALD chambers were given in the above family of disclosures.

Plasma sources have been used to enhance atomic layer deposition processes (PE-ALD). For example, Pomarede et al. in WO 02/43115 A2 teach the use of plasma sources to generate excited reactive species that prepare/activate the substrate surface to facilitate subsequent ALD. Nguyen et al. in WO 02/43114 A2 teach the use of a pulsing plasma to enact ALD processes instead of alternating precursor chemical flows. Again, these publications do not disclose any method to clean the ALD residues after the wafers have been processed.

Although the aforementioned high-k materials are excellent gate insulators, it is very difficult to dry etch these films for pattern transfer. While the deposition process desirably generates high-k films on a substrate (typically a silicon wafer), the reactions that form these films also occur non-productively on other exposed surfaces inside of the deposition chamber. Accumulation of deposition residues results in particle shedding, degradation of deposition uniformity, and processing drifts. These effects can lead to wafer defects and subsequent device failure. Therefore, all CVD chambers, and specifically ALD chambers, must be periodically cleaned.

Due to their extreme chemical inertness, there have been few attempts to dry etch these high-k materials. J. W. Lee et al. in “Electron cyclotron resonance plasma etching of oxides and SrS and ZnS-based electroluminescent materials for flat panel displays”, J. Vac. Sci. Technol. A 16(3), pp. 1944-1948, reported several chemistries to etch various metal oxides and sulfides. The authors used very powerful plasma conditions (800 W of microwave source power, up to 450 W of RF chuck bias power, and chamber pressure of 1.5 mTorr). The result of such process conditions is very high chuck bias voltage (up to −535 V). High chuck bias voltage can greatly enhance energetic ion sputtering and sputtering induced etching. The authors used Cl₂/Ar, BCl₃/Ar, and SF₆/Ar mixture under the extreme plasma conditions to etch various materials. Al₂O₃ showed the slowest etch rates. In most of their experiments, Al₂O₃ etch rates were less than 20% of the ZnS etch rates under identical conditions. The authors also noted “Fairly similar trends were seen with BCl₃/Ar discharges, with the absolute rates being ˜20% lower than that for Cl₂/Ar.” While the authors' method may be used for anisotropic etching of flat panel display devices, high power plasma sputtering cannot be achieved on grounded chamber surfaces. Therefore, the authors' methods cannot be extended to clean deposition residues in ALD chambers.

Williams et al. in U.S. Pat. No. 6,238,582 B1 teach a reactive ion beam etching (RIBE) method to etch thin film head materials such as Al₂O₃. The patentees used a CHF_{3/}Ar plasma as the ion source. Collimated reactive ion beam then impinged upon the wafer substrate to etch thin film materials. Such collimated ion beams cannot be used to clean deposition residues from ALD chambers.

Lagendijk et al. in U.S. Pat. Nos. 5,298,075 and 5,288,662 teach a “process for thermal oxidation of silicon or cleaning of furnace tubes . . . by exposing the silicon or tube to temperatures above 700° C. while flowing a carrier gas containing oxygen and a chlorohydrocarbon having a general formula CₓHₓClₓ where x is 2, 3, or 4 over the silicon or tube. The chlorohydrocarbon is selected to readily and completely oxidize at temperature.” (See Abstract.) Oxidation of silicon into SiO₂ and gettering metal contaminants (such as Na and Fe) in oxidation or diffusion furnaces is a completely different process than etching/cleaning high-k materials.

In view of the dearth of art disclosing dry etching/cleaning of high-k materials, ALD reactors have typically been cleaned by mechanical means (scrubbing or blasting) to clean up the deposition residues from the internal surfaces of the chamber and downstream equipment (e.g. pump headers and exhaust manifolds). However, mechanical cleaning methods are time-consuming and labor-intensive.

Fluorine-containing plasma-based dry cleaning is commonly used to clean up residues of silicon compounds (such as polycrystalline silicon, SiO₂, SiON, and Si₃N₄) and tungsten in chemical vapor deposition (CVD) reactors. However, fluorine-based chemistry is ineffective to remove the high-k dielectric materials discussed above. See, e.g., J. Hong et al., J. Vac. Sci. Technol. A, Vol. 17, pp1326-1330, 1999, wherein the authors exposed Al₂O₃ coated wafers to NF_{3/}Ar based inductively coupled plasmas, and found that “the greater concentration of atomic F available at high source power contributed to thicker fluorinated surfaces, leading to the net deposition rather than etching.”

Thus, there is an urgent need for a process to chemically dry clean high-k residues, such as Al₂O₃, HfO₂, ZrO₂, HfSiₓO_{y}, ZrSiₓO_{y} and mixtures thereof from ALD chambers without venting/opening up the chamber. An effective chemical dry cleaning method will significantly increase the productivity and lower the cost-of-ownership (CoO) of ALD reactors.

All references cited herein are incorporated herein by reference in their entireties.

### BRIEF SUMMARY OF THE INVENTION

Accordingly, the invention provides a process for removing a substance from a substrate, said process comprising:

providing the substrate, wherein: (a) the substrate is at least partially coated with a film of the substance; (b) the substance is at least one member selected from the group consisting of a transition metal oxide, a transition metal silicate, a Group 13 metal oxide and a Group 13 metal silicate; and (c) the substance has a dielectric constant greater than that of silicon dioxide;

reacting the substance with a reactive gas to form a volatile product, wherein the reactive gas comprises chlorine; and

removing the volatile product from the substrate to thereby remove the substance from the substrate,

provided that when the substance is Al₂O₃ and the substrate is a semiconductor from which the substance is being selectively etched, the process is conducted in the absence of a plasma having a density greater than 10¹¹ cm⁻³.

Further provided is a process for removing a substance from a substrate, said process comprising:

providing the substrate, wherein: (a) the substrate is at least partially coated with a film of the substance; (b) the substance is at least one member selected from the group consisting of a transition metal oxide and a transition metal silicate; and (c) the substance has a dielectric constant greater than that of silicon dioxide;

reacting the substance with a reactive gas to form a volatile product, wherein the reactive gas comprises chlorine; and

removing the volatile product from the substrate to thereby remove the substance from the substrate.

Still further provided is a process for cleaning a substance from a reactor surface, said process comprising:

providing a reactor containing the reactor surface, wherein: (a) the reactor surface is at least partially coated with a film of the substance; (b) the substance is at least one member selected from the group consisting of a transition metal oxide, a transition metal silicate, a Group 13 metal oxide and a Group 13 metal silicate; and (c) the substance has a dielectric constant greater than that of silicon dioxide;

reacting the substance with a reactive gas to form a volatile product, wherein the reactive gas comprises chlorine; and

removing the volatile product from the reactor to thereby remove the substance from the substrate.

### BRIEF DESCRIPTION OF SEVERAL VIEWS OF THE DRAWINGS

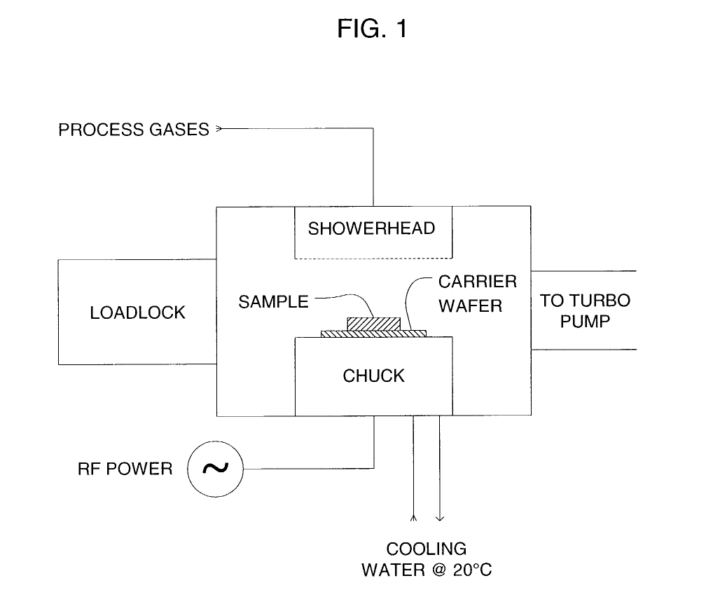

The invention will be described in conjunction with FIG. 1, which shows a schematic view of an apparatus for performing a process of the invention.

### DETAILED DESCRIPTION OF THE INVENTION

The inventive process is useful for dry-etching high-k materials and dry-cleaning chemical vapor deposition (CVD) chambers (and more specifically, ALD chambers) used to deposit high-k materials onto wafer surfaces. The material to be removed from the surface being etched or cleaned is converted from a solid non-volatile material into species that have higher volatility than the high-k materials and, are subsequently removed by reactor vacuum pumps. Thus, in preferred embodiments, the invention removes a substance from a substrate using a reactive gas to volatilize the substance. Unlike wet-etching and wet-cleaning processes, dry-etching and dry-cleaning processes do not immerse the substrate in or expose the substrate to liquid chemical solutions.

The substance to be removed is a transition metal oxide, a transition metal silicate, a Group 13 metal oxide or a Group 13 metal silicate (in accordance with the IUPAC Nomenclature of Inorganic Chemistry, Recommendations 1990, Group 13 metals include Al, Ga, In and TI, and the transition metals occupy Groups 3-12). The substance is a high-k material having a dielectric constant greater than that of silicon dioxide (i.e., greater than about 4.42), more preferably greater than 5, even more preferably at least 7. Preferably, the substance is at least one member selected from the group consisting of Al₂O₃, HfO₂, ZrO₂, HfSiₓO_{y}, ZrSiₓO_{y}, and mixtures thereof. Those skilled in the art will appreciate that the formula HfSiₓO_{y} (and the formula ZrSiₓO_{y}) represents a mixture of HfO₂ (ZrO₂) and SiO₂, where x is greater than 0 and y is 2×+2.

Since the chlorides of these metals (such as AlCl₃, HfCl₄, ZrCl₄, and SiCl₄) are more volatile, it is preferred to convert these high-k substances into chlorides. This conversion is accomplished by contacting the substance to be removed with a reactive gas containing chlorine. Preferred examples of chlorine-containing reactive gases include BCl₃, COCl₂, HCl, Cl₂, ClF₃, and NFₓCl₃₋ₓ, where x is 0 to 2, and chlorocarbons and chlorohydrocarbons (such as CₓH_{y}C_{z} where x=1-6, y=0-13, and z=1-14). Chlorine-containing reactive gases that also contain oxygen-getter functions, such as Bl_{3,} COCl₂, and chlorocarbons and chlorohydrocarbons (such as CₓH_{y}Cl_{z} where x=1-6, y=0-13, and z=1-14) are more preferred because the oxygen-getter component (B, CO, C, or H) in these molecules extracts oxygen from the high-k materials and hence enhances the conversion of metal oxides and metal silicates into metal chlorides. Among the chlorine-containing and oxygen-getter gases, BCl₃ is the most preferred one. In embodiments employing COCl₂ as the reactive gas it can be provided in prepared form or formed by an in situ reaction of CO and Cl₂. In embodiments for removing metal silicates, the reactive gas can comprise a chlorine-containing gas and a fluorine-containing gas (e.g., BCl₃ and BF₃), or a gas containing both fluorine and chlorine such as ClF₃, and NFₓCl₃₋ₓ, where x is 0 to 2. The reactive gases can be delivered by a variety of means, such as conventional cylinders, safe delivery systems, vacuum delivery systems, solid or liquid-based generators that create the reactive gas at the point of use.

In addition to the reactive gases described here, inert diluent gases such as nitrogen, CO2, helium, neon, argon, krypton, and xenon etc. can also be added. Inert diluent gases can modify the plasma characteristics and cleaning processes to better suit some specific applications. The concentration of the inert gases can be 0-99%.

The process of the invention is useful for etching semiconductors and cleaning deposition chambers for semiconductor manufacturing. Thus, suitable substrates for the etching embodiments of the invention include, e.g., semiconductor wafers and the like, while suitable substrates for the cleaning embodiments of the invention include, e.g., surfaces of deposition chambers for CVD and/or ALD.

Thermal or plasma activation and/or enhancement can significantly impact the efficacy of chloro-compound-based etching and cleaning of high-k materials. For thermal activation, the substrate can be heated up to 600° C., more preferably up to 400° C., and even more preferably up to 300° C. The pressure range is generally 10 mTorr to 760 Torr, more preferably 1 Torr to 760 Torr.

For in situ plasma activation, one can generate the plasma with a 13.56 MHz RF power supply, with RF power density at least 0.2 W/cm², more preferably at least 0.5 W/cm², even more preferably at least 1 W/cm². One can also operate the in situ plasma at RF frequencies lower than 13.56 MHz to enhance ion assisted cleaning of grounded ALD chamber walls. The operating pressure is generally in the range of 2.5 mTorr to 100 Torr, more preferably 5 mTorr to 50 Torr, even more preferably 10 mTorr to 20 Torr. Optionally, one can also combine thermal and plasma enhancement for more effective cleaning of ALD chamber walls.

One can also use remote plasma source to replace in situ plasma to generate more reactive species. The remote plasma source can be generated by either an RF or a microwave source. In addition, reactions between remote plasma generated reactive species and high-k materials can be activated/enhanced by heating ALD reactor components to elevated temperatures up to 600° C., more preferably up to 400° C., and even more preferably up to 300° C.

Other means of activation and enhancement to the cleaning processes can also be employed. For example, one can use photon induced chemical reactions to generate reactive species and enhance the etching/cleaning reactions.

The following tables show thermochemical calculations for preferred reactions for volatilizing the substance to be removed from the substrate. In these tables, K_{eq} represents the equilibrium constant for the reaction as written; so that the larger this value is, the more favorable the reaction will be to proceed.

TABLE 1
Al₂O₃ reaction with BCl₃: Al₂O₃ + 2BCl₃(g) [symbol] B₂O₃ + 2AlCl₃(g)

| Temperature (° C.) | ΔH (Kcal) | ΔS (Cal) | ΔG (Kcal) | K_{eq} |
|---|---|---|---|---|
| 0.000 | 9.561 | 12.274 | 6.208 | 1.078E−005 |
| 100.000 | 9.547 | 12.249 | 4.976 | 1.217E−003 |
| 200.000 | 9.424 | 11.959 | 3.766 | 1.822E−002 |
| 300.000 | 9.299 | 11.719 | 2.582 | 1.036E−001 |
| 400.000 | 9.196 | 11.553 | 1.419 | 3.461E−001 |
| 500.000 | 15.123 | 19.739 | −0.138 | 1.094E+000 |
| 600.000 | 15.476 | 20.169 | −2.135 | 3.422E+000 |
| 700.000 | 15.748 | 20.464 | −4.167 | 8.629E+000 |
| 800.000 | 15.951 | 20.664 | −6.224 | 1.852E+001 |
| 900.000 | 16.097 | 20.794 | −8.298 | 3.515E+001 |
| 1000.000 | 16.190 | 20.871 | −10.381 | 6.056E+001 |

TABLE 2
HfO₂ reaction with BCl₃: 1.5HfO₂ + 2BCl₃(g) [symbol] 1.5HfCl₄(g) + B₂O₃

| Temperature (° C.) | ΔH (Kcal) | ΔS (Cal) | ΔG (Kcal) | K_{eq} |
|---|---|---|---|---|
| 0.000 | −17.999 | −12.638 | −14.547 | 4.367E+011 |
| 25.000 | −18.003 | −12.653 | −14.231 | 2.707E+010 |
| 50.000 | −18.025 | −12.721 | −13.914 | 2.576E+009 |
| 75.000 | −18.057 | −12.817 | −13.595 | 3.426E+008 |
| 100.000 | −18.096 | −12.924 | −13.273 | 5.950E+007 |
| 125.000 | −18.138 | −13.034 | −12.948 | 1.283E+007 |
| 150.000 | −18.182 | −13.141 | −12.621 | 3.305E+006 |
| 175.000 | −18.226 | −13.242 | −12.291 | 9.879E+005 |
| 200.000 | −18.268 | −13.335 | −11.959 | 3.346E+005 |

TABLE 3
ZrO₂ reaction with BCl₃: 1.5ZrO₂ + 2BCl₃(g) [symbol] 1.5ZrCl₄(g) + B₂O₃

| Temperature (° C.) | ΔH (Kcal) | ΔS (Cal) | ΔG (Kcal) | K_{eq} |
|---|---|---|---|---|
| 0.000 | −29.845 | −12.107 | −26.538 | 1.717E+021 |
| 25.000 | −29.825 | −12.038 | −26.236 | 1.710E+019 |
| 50.000 | −29.822 | −12.026 | −25.935 | 3.481E+017 |
| 75.000 | −29.828 | −12.047 | −25.634 | 1.239E+016 |
| 100.000 | −29.842 | −12.083 | −25.333 | 6.891E+014 |
| 125.000 | −29.858 | −12.126 | −25.030 | 5.502E+013 |
| 150.000 | −29.875 | −12.168 | −24.726 | 5.913E+012 |
| 175.000 | −29.892 | −12.207 | −24.422 | 8.142E+011 |
| 200.000 | −29.908 | −12.240 | −24.116 | 1.381E+011 |

TABLE 4
HfO₂ reaction with COCl₂: HfO₂ + 2COCl₂(g) [symbol] HfCl₄(g) + 2CO₂(g)

| Temperature (° C.) | ΔH (Kcal) | ΔS (Cal) | ΔG (Kcal) | K_{eq} |
|---|---|---|---|---|
| 0.000 | −20.643 | 41.960 | −32.105 | 4.890E+025 |
| 25.000 | −20.649 | 41.940 | −33.153 | 2.014E+024 |
| 50.000 | −20.668 | 41.878 | −34.201 | 1.357E+023 |
| 75.000 | −20.699 | 41.787 | −35.247 | 1.343E+022 |
| 100.000 | −20.739 | 41.677 | −36.290 | 1.806E+021 |
| 125.000 | −20.786 | 41.554 | −37.331 | 3.112E+020 |
| 150.000 | −20.840 | 41.423 | −38.368 | 6.578E+019 |
| 175.000 | −20.900 | 41.285 | −39.402 | 1.647E+019 |
| 200.000 | −20.965 | 41.144 | −40.432 | 4.757E+018 |

TABLE 5
ZrO₂ reaction with COCl₂: ZrO₂ + 2COCl₂(g) [symbol] ZrCl₄(g) + 2CO₂(g)

| Temperature (° C.) | ΔH (Kcal) | ΔS (Cal) | ΔG (Kcal) | K_{eq} |
|---|---|---|---|---|
| 0.000 | −28.540 | 42.313 | −40.098 | 1.218E+032 |
| 25.000 | −28.530 | 42.350 | −41.157 | 1.483E+030 |
| 50.000 | −28.533 | 42.341 | −42.215 | 3.573E+028 |
| 75.000 | −28.547 | 42.300 | −43.273 | 1.469E+027 |
| 100.000 | −28.569 | 42.238 | −44.330 | 9.244E+025 |
| 125.000 | −28.599 | 42.160 | −45.385 | 8.215E+024 |
| 150.000 | −28.636 | 42.071 | −46.438 | 9.694E+023 |
| 175.000 | −28.678 | 41.975 | −47.489 | 1.448E+023 |
| 200.000 | −28.724 | 41.873 | −48.537 | 2.638E+022 |

TABLE 6
ZrSiO₄ reaction with BCl₃:
ZrSiO₄ + 2.667BCl₃(g) [symbol] ZrCl₄(g) + 1.333B₂O₃

| Temperature (° C.) | ΔH (Kcal) | ΔS (Cal) | ΔG (Kcal) | K_{eq} |
|---|---|---|---|---|
| 0.000 | −31.065 | −21.096 | −25.303 | 1.764E+020 |
| 25.000 | −31.003 | −20.879 | −24.778 | 1.460E+018 |
| 50.000 | −30.962 | −20.747 | −24.258 | 2.554E+016 |
| 75.000 | −30.935 | −20.665 | −23.740 | 8.020E+014 |
| 100.000 | −30.916 | −20.613 | −23.224 | 4.013E+013 |
| 125.000 | −30.902 | −20.577 | −22.710 | 2.928E+012 |
| 150.000 | −30.891 | −20.549 | −22.196 | 2.914E+011 |
| 175.000 | −30.879 | −20.523 | −21.682 | 3.755E+010 |
| 200.000 | −30.867 | −20.496 | −21.169 | 6.012E+009 |
| 225.000 | −30.852 | −20.466 | −20.657 | 1.158E+009 |
| 250.000 | −30.835 | −20.432 | −20.146 | 2.612E+008 |
| 275.000 | −30.814 | −20.393 | −19.636 | 6.754E+007 |
| 300.000 | −30.790 | −20.349 | −19.127 | 1.967E+007 |
| 325.000 | −30.761 | −20.300 | −18.618 | 6.358E+006 |
| 350.000 | −30.729 | −20.247 | −18.112 | 2.252E+006 |
| 375.000 | −30.692 | −20.190 | −17.606 | 8.652E+005 |
| 400.000 | −30.652 | −20.130 | −17.102 | 3.572E+005 |
| 425.000 | −30.608 | −20.066 | −16.600 | 1.573E+005 |
| 450.000 | −22.891 | −9.391 | −16.100 | 7.349E+004 |
| 475.000 | −22.663 | −9.081 | −15.869 | 4.327E+004 |
| 500.000 | −22.443 | −8.791 | −15.646 | 2.649E+004 |

TABLE 7
ZrSiO₄ reaction with BF₃ and BCl₃:
ZrSiO₄ + 1.333BF₃(g) + 1.333BCl₃(g) [symbol] SiF₄(g) + ZrCl₄(g) + 1.333B₂O₃

| Temperature (° C.) | ΔH (Kcal) | ΔS (Cal) | ΔG (Kcal) | K_{eq} |
|---|---|---|---|---|
| 0.000 | −25.010 | −21.014 | −19.270 | 2.627E+015 |
| 25.000 | −24.951 | −20.807 | −18.748 | 5.540E+013 |
| 50.000 | −24.912 | −20.681 | −18.229 | 2.136E+012 |
| 75.000 | −24.885 | −20.600 | −17.713 | 1.319E+011 |
| 100.000 | −24.865 | −20.545 | −17.199 | 1.186E+010 |
| 125.000 | −24.849 | −20.502 | −16.686 | 1.445E+009 |
| 150.000 | −24.833 | −20.463 | −16.174 | 2.260E+008 |
| 175.000 | −24.816 | −20.423 | −15.663 | 4.354E+007 |
| 200.000 | −24.796 | −20.380 | −15.153 | 9.992E+006 |
| 225.000 | −24.772 | −20.332 | −14.644 | 2.661E+006 |
| 250.000 | −24.745 | −20.278 | −14.136 | 8.053E+005 |
| 275.000 | −24.712 | −20.218 | −13.630 | 2.721E+005 |
| 300.000 | −24.675 | −20.152 | −13.125 | 1.012E+005 |
| 325.000 | −24.633 | −20.080 | −12.622 | 4.095E+004 |
| 350.000 | −24.586 | −20.003 | −12.121 | 1.784E+004 |
| 375.000 | −24.535 | −19.922 | −11.622 | 8.303E+003 |
| 400.000 | −24.478 | −19.837 | −11.125 | 4.095E+003 |
| 425.000 | −24.418 | −19.749 | −10.630 | 2.128E+003 |
| 450.000 | −16.684 | −9.050 | −10.139 | 1.160E+003 |
| 475.000 | −16.439 | −8.717 | −9.917 | 7.894E+002 |
| 500.000 | −16.201 | −8.405 | −9.703 | 5.535E+002 |

Tables 1-7 show that BCl₃ and COCl₂ can be used as the etchants for dry etching and cleaning of the high-k materials. BCl₃ (boron trichloride) is a liquefied gas at room temperature and can be readily delivered into ALD reactors for chamber cleaning. COCl₂ (phosgene) is preferably provided in situ in etch or deposition reactors by reacting carbon monoxide and chlorine to form phosgene assisted by an external energy source (e.g. plasma):

CO (g)+Cl₂ (g)→COCl₂

The above thermochemical calculations are illustrations of limiting cases for those chemical reactions. In addition to the limiting case reaction products such as B₂O₃, intermediate reaction products such as boron oxychloride (BOCl) can also be formed in reactions between high-k materials and BCl₃. Intermediate reaction products such as BOCl have higher volatility, thus may further enhance the removal of high-k materials.

In addition to being thermodynamically favorable, a chemical reaction often requires external energy source to overcome an activation energy barrier so that the reaction can proceed. The external energy source can be either from thermal heating or plasma activation. Higher temperature can accelerate chemical reactions, and make reaction byproducts more volatile. However, there may be practical limitations on temperature in production deposition chambers. Plasmas can generate more reactive species to facilitate reactions. Ions in the plasmas are accelerated by the electric field in the plasma sheath to gain energy. Energetic ions impinging upon surfaces can provide the energy needed to overcome reaction activation energy barrier. Ion bombardment also helps to volatize and removes reaction byproducts. These are common mechanisms in plasma etching/cleaning and reactive ion etching. Optionally, one can combine both thermal and plasma activation mechanisms to enhance the desired reactions for dry etching/cleaning of high-k materials. As an alternative to in situ plasma cleaning, one can use remote plasma source to generate more reactive species for cleaning high-k material residues from the deposition chambers. In addition, reactions between remote plasma generated reactive species and high-k materials can be activated/enhanced by heating CVD or ALD reactor components to elevated temperatures up to 600° C., more preferably up to 400° C., and even more preferably up to 300° C.

### EXAMPLES

The invention will be illustrated in more detail with reference to the following Examples, but it should be understood that the present invention is not deemed to be limited thereto.

The following are experimental examples of utilizing the above chemistries for dry etching/cleaning of high-k materials. All the experiments were done in a parallel plate capacitively coupled RF plasma reactor. FIG. 1 is a schematic of the setup. Sample coupons were prepared from wafers coated with high-k dielectric materials Al₂O₃, HfO₂, and ZrO₂ deposited by atomic layer deposition. For each experimental run, a sample coupon was put onto a carrier wafer and loaded onto the reactor chuck through a loadlock. Process gases were fed into the reactor from a top mounted showerhead. The chuck was then powered by a 13.56 MHz RF power source to generate the plasma. The thickness of the high-k film on a coupon was measured by ellipsometry both before and after a timed exposure of the processing plasma. Change in high-k film thickness after plasma processing is used to calculate the etch rate. In addition to etch rate, plasma dc self bias voltage (V_{dc}) was also measured. In all of the examples here, both the wafer and the chamber walls were kept at room temperature.

### Example 1

Etching/Cleaning of Al₂O₃ Samples

Since power is one of the key processing parameters in plasma etching/cleaning, we evaluated power dependence of Al₂O₃ etching by BCl₃ plasma. The results are listed in Table 8 below.

TABLE 8
RF power dependence of Al₂O₃ etching by BCl₃ plasma

| | Power density | Pressure | Al₂O₃ etch rate | |
|---|---|---|---|---|
| Power (W) | (W/cm²) | (mTorr) | (nm/min) | V_{dc} (V) |
| 50 | 0.27 | 500 | 0.0 | −16 |
| 100 | 0.55 | 500 | 3.0 | −35 |
| 200 | 1.10 | 500 | 9.8 | −58 |

Apparently there is threshold power density of 0.55 W/cm² or threshold V_{dc} of −35 V for etching Al₂O₃. Higher power density and higher V_{dc} resulted in higher etch rate.

Next, we investigated chamber pressure dependence of Al₂O₃ etching by BCl₃ plasma. The results are listed in Table 9 below.

TABLE 9
Chamber pressure dependence of Al₂O₃ etching by BCl₃ plasma

| | Power density | Pressure | Al₂O₃ etch rate | |
|---|---|---|---|---|
| Power (W) | (W/cm²) | (mTorr) | (nm/min) | V_{dc} (V) |
| 100 | 0.55 | 50 | 7.2 | −91 |
| 100 | 0.55 | 500 | 3.0 | −35 |
| 100 | 0.55 | 1000 | 0.8 | −4 |

Higher etch rate was achieved at reduced pressure. There are two factors favor the etch reactions at reduced pressure. First, higher V_{dc} at lower pressure leads to more energetic ion bombardment to help the etch reactions to overcome activation energy barrier. Second, lower pressure leads to faster desorption and diffusion of reaction byproducts. Higher V_{dc} also enhances physical sputtering by energetic ions. To delineate the contributions from reactive ion etching and physical sputtering, we conducted comparison runs using pure argon plasma. The results are listed in Table 10 below.

TABLE 10
Argon plasma etching of Al₂O₃

| | Power density | Pressure | Al₂O₃ etch rate | |
|---|---|---|---|---|
| Power (W) | (W/cm²) | (mTorr) | (nm/min) | V_{dc} (V) |
| 200 | 1.10 | 5 | 0.6 | −173 |
| 200 | 1.10 | 50 | 1.0 | −189 |
| 200 | 1.10 | 500 | −0.4 | −185 |

The data showed that pure argon plasma essentially did not etch Al₂O₃ even with very high power and much higher V_{dc} than that of BCl₃ plasmas. This clarifies that physical sputtering is not the primary mechanism to etch Al₂O₃. Instead, ion bombardment enhanced chemical etching, or reactive ion etching (RIE) is the primary mechanism.

Tables 8 and 9 showed that higher power and lower pressure can increase V_{dc}, which in turn enhances chemical etching of high-k materials. Once can also operate the RF plasma at lower frequencies. Ions transiting through a plasma sheath often exhibit bi-modal energy distribution at lower frequencies. Bimodal ion energy distribution results in a large fraction of the ions impinging onto reactor surfaces. This can be an effective strategy to enhance plasma cleaning of high-k deposition residues from grounded ALD chamber surfaces. At a fixed RF excitation frequency (such as 13.56 MHz), the data in Tables 8 and 9 shows that higher power and lower pressure can increase V_{dc}, which in turn enhances chemical etching of high-k materials. Lower pressure and higher power is particularly effective to enhance plasma etching of substrates coated with high-k films. For ALD chamber cleaning, one must balance the requirements between RF powered reactor components and ground reactor components (such as chamber walls). We chose chamber pressure of 500 mTorr for other examples illustrated here.

### Example 2

Etching/Cleaning of HfO₂ Samples

At 500 mTorr pressure, etching of HfO₂ was achieved at all power levels between 50 and 200 W. The results are listed in Table 11 below.

TABLE 11
BCl₃ plasma etching of HfO₂

| | Power density | Pressure | HfO₂ etch rate | |
|---|---|---|---|---|
| Power (W) | (W/cm²) | (mTorr) | (nm/min) | V_{dc} (V) |
| 50 | 0.27 | 500 | 1.6 | −14 |
| 50 | 0.27 | 500 | 1.4 | −16 |
| 100 | 0.55 | 500 | 4.7 | −34 |
| 200 | 1.10 | 500 | 14.7 | −63 |

### Example 3

Etching/Cleaning of ZrO₂ Samples

Several experiments were conducted with ZrO₂ samples. The results are listed in Table 12 below.

TABLE 12
BCl₃ plasma etching of HfO₂

| | Power density | Pressure | ZrO₂ etch rate | |
|---|---|---|---|---|
| Power (W) | (W/cm²) | (mTorr) | (nm/min) | V_{dc} (V) |
| 50 | 0.27 | 500 | 0.3 | −16 |
| 100 | 0.55 | 500 | −3.8* | −32 |
| 100 | 0.55 | 500 | −2.5* | −45 |
| 200 | 1.10 | 500 | 7.1 | −65 |

*The film became thicker after one minute exposure to the plasma.

While the invention has been described in detail and with reference to specific examples thereof, it will be apparent to one skilled in the art that various changes and modifications can be made therein without departing from the spirit and scope thereof.

1. A process for removing a substance from a substrate, said process comprising:
providing the substrate, wherein: (a) the substrate is at least partially coated with a film of the substance; (b) the substance is at least one member selected from the group consisting of a transition metal oxide, a transition metal silicate, a Group 13 metal oxide and a Group 13 metal silicate; and (c) the substance has a dielectric constant greater than a dielectric constant of silicon dioxide;
reacting the substance with a reactive gas to form a volatile product, wherein the reactive gas comprises chlorine; and
removing the volatile product from the substrate to thereby remove the substance from the substrate,
provided that when the substance is Al₂O₃ and the substrate is a semiconductor from which the substance is being selectively etched, the process is conducted in the absence of a plasma having a density greater than 10¹¹ cm⁻³.

2. The process of claim 1, wherein the substance is at least one member selected from the group consisting of Al₂O₃, HfO₂, ZrO₂, HfSiₓO_{y} and ZrSiₓ O_{y}.

3. The process of claim 1, wherein the reactive gas is at least one member selected from the group consisting of BCl₃, COCl₂, HCl, Cl₂, ClF₃, and NF_{z}Cl_{3-z}, where z is 0 to 2.

4. The process of claim 3, wherein the substance is at least one member selected from the group consisting of Al₂O₃, HfO₂, ZrO₂, HfSiₓO_{y} and ZrSiₓO_{y}.

5. The process of claim 4, wherein the reactive gas is COCl₂ formed by an in situ reaction of CO and Cl₂.

6. The process of claim 4, wherein the reactive gas is BCl3.

7. The process of claim 1, wherein the reactive gas is conveyed to the substance from a gas cylinder, a safe delivery system or a vacuum delivery system.

8. The process of claim 1, wherein the reactive gas is formed in situ by a point-of-use generator.

9. The process of claim 1, wherein the substance is contacted with the reactive gas diluted with an inert gas diluent.

10. The process of claim 1, wherein the substrate is a semiconductor and the process etches selected portions of the substance from the semiconductor.

11. The process of claim 1, wherein the substrate is a deposition chamber and the process cleans deposition residue from the deposition chamber.

12. The process of claim 1, wherein the substance is coated on the substrate by atomic layer deposition.

13. A process for removing a substance from a substrate, said process comprising:
providing the substrate, wherein: (a) the substrate is at least partially coated with a film of the substance; (b) the substance is at least one member selected from the group consisting of a transition metal oxide and a transition metal silicate; and (c) the substance has a dielectric constant greater than a dielectric constant of silicon dioxide;
reacting the substance with a reactive gas to form a volatile product, wherein the reactive gas comprises chlorine; and
removing the volatile product from the substrate to thereby remove the substance from the substrate.

14. The process of claim 13, wherein the substance is at least one member selected from the group consisting of HfO2, ZrO2, HfSixOy, and ZrSixOy, and the reactive gas is at least one member selected from the group consisting of BCl3, COCl2, HCl, Cl2, ClF3, and NFzCl3−z, where z is 0 to 2.

15. The process of claim 14, wherein the substrate is a semiconductor and the process etches selected portions of the substance from the semiconductor.

16. The process of claim 14, wherein the substrate is a deposition chamber and the process cleans deposition residue from the deposition chamber.

17. A process for cleaning a substance from a reactor surface, said process comprising:
providing a reactor containing the reactor surface, wherein: (a) the reactor surface is at least partially coated with a film of the substance; (b) the substance is at least one member selected from the group consisting of a transition metal oxide, a transition metal silicate, a Group 13 metal oxide and a Group 13 metal silicate; and (c) the substance has a dielectric constant greater than a dielectric constant of silicon dioxide;
reacting the substance with a reactive gas to form a volatile product, wherein the reactive gas comprises chlorine; and
removing the volatile product from the reactor to thereby remove the substance from the substrate.

18. The process of claim 17, wherein the reactor is an atomic layer deposition reactor.

19. The process of claim 18, wherein the substance is at least one member selected from the group consisting of Al₂O₃, HfO₂, ZrO₂, HfSiₓO_{y}, and ZrSiₓO_{y}, and the reactive gas is at least one member selected from the group consisting of BCl₃, COCl₂, HCl, Cl₂, ClF₃, and NF_{z}Cl_{3-z}, where z is 0 to 2.

20. A process for cleaning a substance from a reactor surface, said process comprising:
providing a reactor containing the reactor surface, wherein: (a) the reactor surface is at least partially coated with the substance; (b) the substance is at least one member selected from the group consisting of Al₂O₃, HfO₂, ZrO₂, HfSiₓO_{y} and ZrSiₓO_{y}; and (c) the substance has a dielectric constant greater than a dielectric constant of silicon dioxide;
reacting the substance with a reactive gas to form a volatile product, wherein the reactive gas comprises chlorine; and
removing the volatile product from the reactor to thereby remove the substance from the substrate.
